(19) United States
(12) Patent Application Publication
(10) Pub. No.: US 2025/0267799 A1
(43) Pub. Date: Aug. 21, 2025

(54) METHOD FOR MANUFACTURING WIRING BOARD, METHOD FOR EVALUATING RESIST LAYER OR WIRING BOARD, AND WIRING BOARD

(71) Applicant: Resonac Corporation, Minato-ku, Tokyo (JP)

(72) Inventors: Kei TOGASAKI, Minato-ku, Tokyo (JP); Kenichi IWASHITA, Minato-ku, Tokyo (JP); Keishi ONO, Minato-ku, Tokyo (JP); Mao NARITA, Minato-ku, Tokyo (JP); Kazuyuki MITSUKURA, Minato-ku, Tokyo (JP); Masaya TOBA, Minato-ku, Tokyo (JP)

(21) Appl. No.: 18/857,460

(22) PCT Filed: Aug. 9, 2023
(86) PCT No.: PCT/JP2023/029150

§ 371 Date: Oct. 17, 2024

(30) Foreign Application Priority Data
Aug. 10, 2022 (WO) PCT/JP2022/030593

(51) Int. Cl. H05K 3/18; H05K 1/02; H05K 3/24

(52) U.S. Cl. CPC H05K 3/188; H05K 1/0298; H05K 3/241

(57) ABSTRACT

A method for manufacturing a wiring board, the method including: providing a resist layer on a seed layer containing a metal, the seed layer being provided on a main surface of a substrate; forming a pattern including an opening through which the seed layer is exposed on the resist layer by exposure and development of the resist layer; and forming a copper plating layer including a portion having a width of less than 10 μm on the seed layer exposed in the opening by electrolytic plating. The copper plating layer is formed so that a BP occupancy, which is an occupancy of a black portion observed in a cross section of a metal portion including the seed layer and the copper plating layer in a width direction of the copper plating layer, is 45% or less. The resist layer is selected. The BP occupancy is a value as determined by a method including calculating the BP occupancy according to the following equation:

$$BP occupancy ( \% ) = {\sum }_{i = 1}^{n} {w}_{i} \times \frac{1}{L} \times 100 .$$

### TECHNICAL FIELD

The present disclosure relates to a method for manufacturing a wiring board, a method for evaluating a resist layer or a wiring board, and a wiring board.

### BACKGROUND ART

A wiring board constituting an electronic device is required to have a wiring having a minute width in order to meet a demand for reduction in size, reduction in weight, and increase in speed of the electronic device. As a method for forming a wiring having a minute width, a semi-additive (SAP) method and a modified semi-additive (MSAP) method are widely used (Patent Literature 1). These methods generally include a step of forming a copper plating layer on a seed layer by electrolytic plating. The seed layer is usually formed by electroless plating in SAP, and is formed by laminating a copper foil in MSAP.

### CITATION LIST

### Patent Literature

Patent Literature 1: Japanese Unexamined Patent Publication No. 2004-6773
Patent Literature 2: International Patent Publication No. 2022/054873

### SUMMARY OF INVENTION

### Technical Problem

When a fine wiring is formed on the seed layer by the copper plating layer including a portion having a width of less than 10 μm, adhesion between the seed layer and the copper plating layer may be insufficient. For example, when an unnecessary portion of the seed layer is removed by an etching liquid, the copper plating layer (wiring) can easily collapse. One aspect of the present disclosure relates to improving adhesion between a seed layer and a copper plating layer when a wiring board is manufactured by a method including forming a copper plating layer including a portion having a width of less than 10 μm on the seed layer by electrolytic plating.

### Solution to Problem

The present disclosure includes at least the following means.
[1] A method for manufacturing a wiring board, the method including:
providing a resist layer on a seed layer comprising a metal, the seed layer being provided on a main surface of a substrate;
forming a pattern including an opening through which the seed layer is exposed at the resist layer by exposure and development of the resist layer; and
forming a copper plating layer comprising a portion having a width of less than 10 μm on the seed layer exposed in the opening by electrolytic plating, wherein
the copper plating layer is formed so that a BP occupancy that is an occupancy of a black portion observed in a cross section of a metal portion comprising the seed layer and the copper plating layer in a width direction of the copper plating layer, is 45% or less, and
the BP occupancy is a value as determined by a method including:
determining a number n of black portions observed in a region having a width of L [μm] in a direction parallel to the main surface of the substrate in a cross section of the metal portion comprising the copper plating layer having a width of less than 10 μm;
determining a maximum width wᵢ [μm] of each of the n black portions in a direction parallel to the main surface of the substrate; and
calculating the BP occupancy according to the following equation:

$$BP occupancy ( \% ) = {\sum }_{i = 1}^{n} {w}_{i} \times \frac{1}{L} \times 100 .$$

[2] The method according to [1], further including:
removing the resist layer to expose a portion of the seed layer that is not covered with the copper plating layer; and
removing an exposed portion of the seed layer with an etching liquid to form a wiring board including: a wiring comprising the seed layer and the copper plating layer; and the substrate.
[3] The method according to [1] or [2], wherein the resist layer comprises a binder polymer, a photopolymerizable component, and a photopolymerization initiator, and the resist layer is selected so that the BP occupancy is 45% or less.
[4] The method according to [3], wherein the photopolymerization initiator comprises a 2,4,5-triarylimidazole dimer derivative.
[5] The method according to [4], wherein a content of the 2,4,5-triarylimidazole dimer derivative in the resist layer is selected in a range of 6 parts by mass or more and 12 parts by mass or less with respect to 100 parts by mass of a 7 total amount of the binder polymer and the photopolymerizable component.
[6] The method according to any one of [3] to [5], wherein the photopolymerizable component comprises a photopolymerizable compound having an oxyalkylene group.
[7] A method for evaluating a resist layer, the method including:
providing a resist layer on a seed layer comprising a metal, the seed layer being provided on a main surface of a substrate;
forming a pattern including an opening through which the seed layer is exposed at the resist layer by exposure and development of the resist layer;
forming a copper plating layer comprising a portion having a width of less than 10 μm on the seed layer exposed in the opening by electrolytic plating; and
determining a BP occupancy that is an occupancy of a black portion observed in a cross section of a metal portion comprising the seed layer and the copper plating layer in a width direction of the copper plating layer,
wherein a method for determining the BP occupancy includes:
determining a number n of black portions observed in a region having a width of L [μm] in a direction parallel to a main surface of the substrate in a cross section of the metal portion including the copper plating layer having a width of less than 10 μm;
determining a maximum width wᵢ [μm] of each of the n black portions in a direction parallel to the main surface of the substrate; and
calculating the BP occupancy according to the following equation:

$$BP occupancy ( \% ) = {\sum }_{i = 1}^{n} {w}_{i} \times \frac{1}{L} \times 100 .$$

[8] A method for evaluating a wiring board including: a substrate; and a wiring provided on the substrate, wherein
the wiring comprises: a seed layer provided on the substrate; and a copper plating layer comprising a portion having a width of less than 10 μm, the copper plating layer being formed on the seed layer,
the method includes determining a BP occupancy that is an occupancy of a black portion observed in a cross section of the wiring in a width direction of the copper plating layer, and
a method for determining the BP occupancy includes:
determining a number n of black portions observed in a region having a width of L [μm] in a direction parallel to a main surface of the substrate in a cross section of the wiring comprising the copper plating layer having a width of less than 10 μm;
determining a maximum width wᵢ [μm] of each of the n black portions in a direction parallel to the main surface of the substrate; and
calculating the BP occupancy according to the following equation:
[9] A wiring board including:
a substrate; and
a wiring provided on the substrate, wherein
the wiring comprises: a seed layer provided on the substrate; and a copper plating layer comprising a portion having a width of less than 10 μm, the copper plating layer being formed on the seed layer,
a BP occupancy that is an occupancy of a black portion observed in a cross section of the wiring in a width direction of the copper plating layer, is 45% or less, and
the BP occupancy is a value as determined by a method including:
determining a number n of black portions observed in a region having a width of L [μm] in a direction parallel to a main surface of the substrate in a cross section of the wiring comprising the copper plating layer having a width of less than 10 μm;
determining a maximum width wᵢ [μm] of each of the n black portions in a direction parallel to the main surface of the substrate; and
calculating the BP occupancy according to the following equation:

$$BP occupancy ( \% ) = {\sum }_{i = 1}^{n} {w}_{i} \times \frac{1}{L} \times 100 .$$

### Advantageous Effects of Invention

Adhesion between a seed layer and a copper plating layer can be improved when a wiring board is manufactured by a method including forming a copper plating layer on the seed layer by electrolytic plating.

### BRIEF DESCRIPTION OF DRAWINGS

FIG. 1 is a process diagram illustrating an example of a method for manufacturing a wiring board.

FIG. 2 is a process diagram illustrating the example of the method for manufacturing a wiring board.

FIG. 3 is a cross-sectional view illustrating an example of a region observed for determining a BP occupancy in a cross section of a metal portion.

FIG. 4 is an example of a scanning electron microscope image of the cross section of the metal portion.

FIG. 5 is an image obtained by binarizing a portion of the metal portion in the scanning electron microscope image of FIG. 4.

FIG. 6 is a graph illustrating a relationship between a peel strength of a copper plating layer and a number density of black portions (BP number density).

FIG. 7 is a graph illustrating a relationship between the peel strength of the copper plating layer and an average area Sₘ of the black portions.

FIG. 8 is a graph illustrating a relationship between the peel strength of the copper plating layer and a total Sₜₒₜₐₗ of the black portions.

FIG. 9 is a graph illustrating a relationship between the peel strength of the copper plating layer and the BP occupancy.

### DESCRIPTION OF EMBODIMENTS

The present invention is not limited to the following examples.

The term “(meth)acrylic” in the present specification means both “methacrylic” and “acrylic”. Other similar terms have similar meanings.

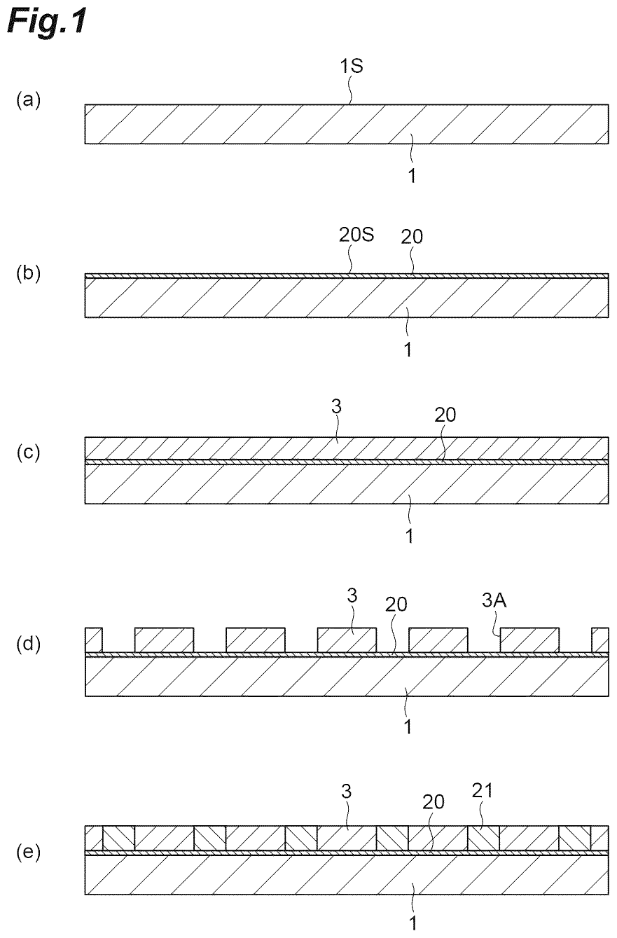

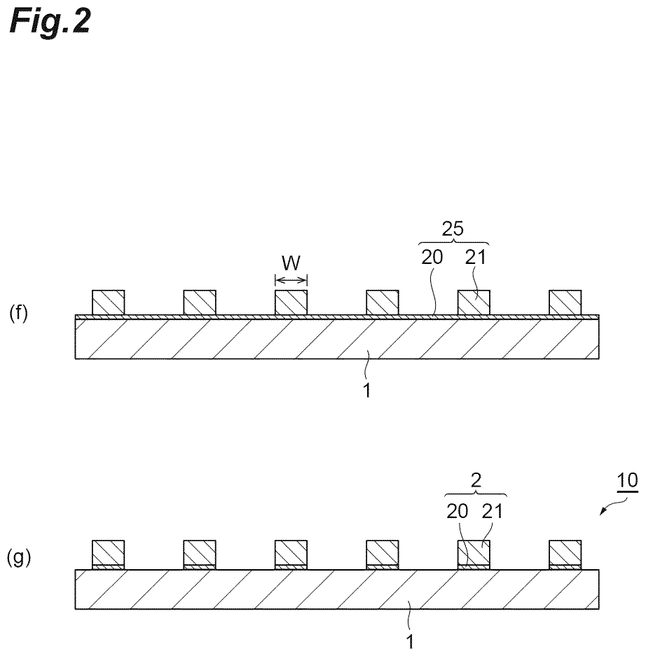

FIGS. 1 and 2 are process diagrams illustrating an example of a method for manufacturing a wiring board. A method as illustrated in FIGS. 1 and 2 includes, in this order, a step of forming a seed layer 20 containing metal on one main surface 1S of a plate-shaped substrate 1, a step of providing a resist layer 3 containing a resist material on a surface 20S of the seed layer 20 opposite to the substrate 1, a step of forming a pattern including an opening 3A through which the seed layer 20 is exposed at the resist layer 3 by exposure and development of the resist layer 3, a step of forming a copper plating layer 21 on the seed layer 20 by electrolytic plating, a step of removing the resist layer 3 to expose a portion of the seed layer 20 that is not covered with the copper plating layer 21, and a step of removing an exposed portion of the seed layer 20 to form a wiring board 10 including: a wiring 2 including the seed layer 20 and the copper plating layer 21; and the substrate 1. The wiring 2 is formed by removing a portion of the seed layer 20 that is not covered with the copper plating layer 21 from a metal portion 25 composed of the seed layer 20 and the copper plating layer 21.

The substrate 1 can be a plate-shaped body capable of supporting the wiring 2. An outermost layer of the substrate 1 on a side where the seed layer 20 is provided is usually composed mainly of an insulating layer. The insulating layer provided as the outermost layer of the substrate 1 may be an insulating resin layer such as a build-up layer. The substrate 1 may include a wiring connected to the wiring 2.

The seed layer 20 is a layer containing a metal, and is provided for electrolytic plating. The seed layer 20 can be, for example, a metal plating layer formed by electroless plating, a metal foil such as a copper foil, a metal layer formed by vapor deposition such as sputtering, or a metal sintered layer. The metal sintered layer is a layer formed by heating a coating film containing metal particles and sintering the metal particles. The seed layer 20 may contain, for example, at least one metal selected from the group consisting of copper, gold, silver, tungsten, molybdenum, tin, cobalt, chromium, iron, zinc, nickel, and titanium. The seed layer 20 may be a single layer or may be composed of two or more layers. A thickness of the seed layer 20 may be, for example, 100 nm or more or 200 nm or more, and may be 2000 nm or less or 1000 nm or less.

When a cross section of the metal portion 25 (or the wiring 2) including the seed layer 20 and the copper plating layer 21 is observed with a scanning electron microscope, a minute black portion may be observed. The black portion is typically distributed in the vicinity of an interface between the seed layer 20 and the copper plating layer 21. The present inventors infer that the black portion is some defective portion such as a minute void, which is related to adhesion between the copper plating layer 21 and the seed layer 20. It is considered that the black portion is generated mainly due to a trace amount of the resist layer remaining on the seed layer. According to findings by the present inventors, a small occupancy of the black portion in a width direction (direction parallel to the main surface 1S of the substrate 1) of the copper plating layer 21 leads to a tendency of increasing the adhesion between the copper plating layer 21 and the seed layer 20. The number of black portions may also affect the adhesion, but, particularly in a case of a fine wiring, the occupancy of the black portion affects the adhesion more greatly than the number of black portions. Hereinafter, this occupancy is sometimes referred to as BP occupancy, and is determined by a method which is described below.

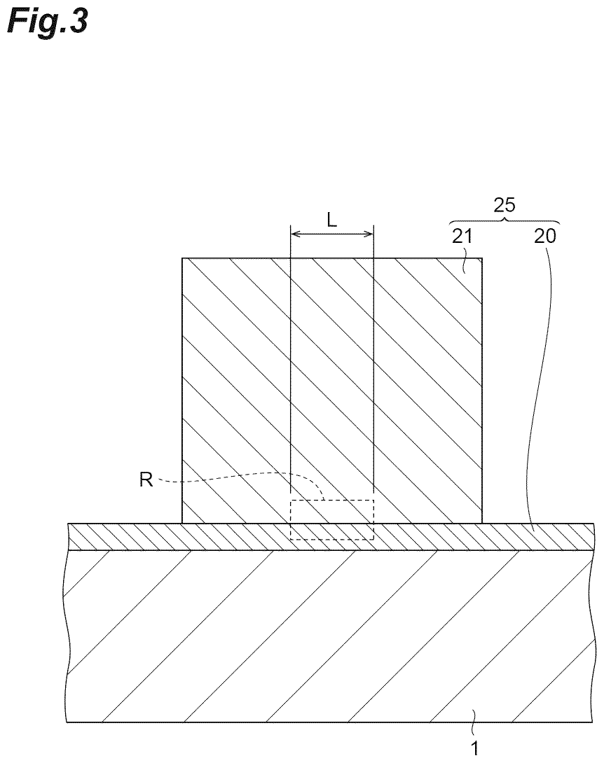

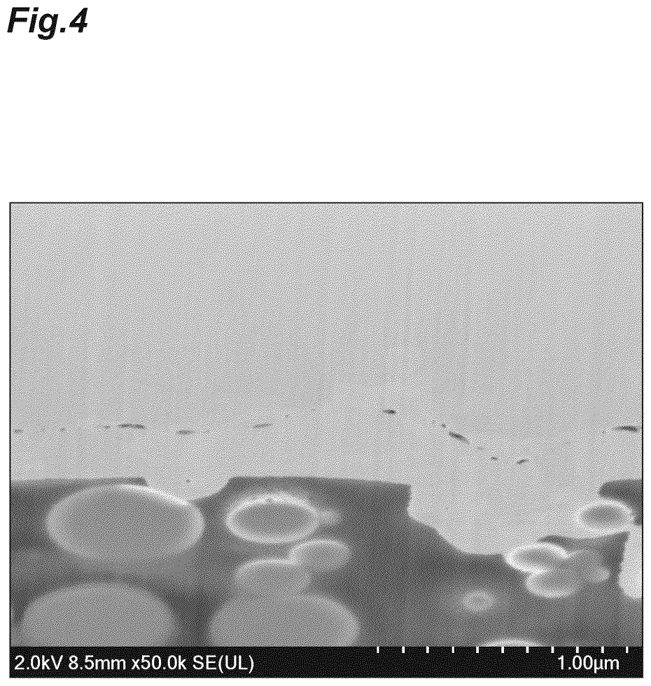

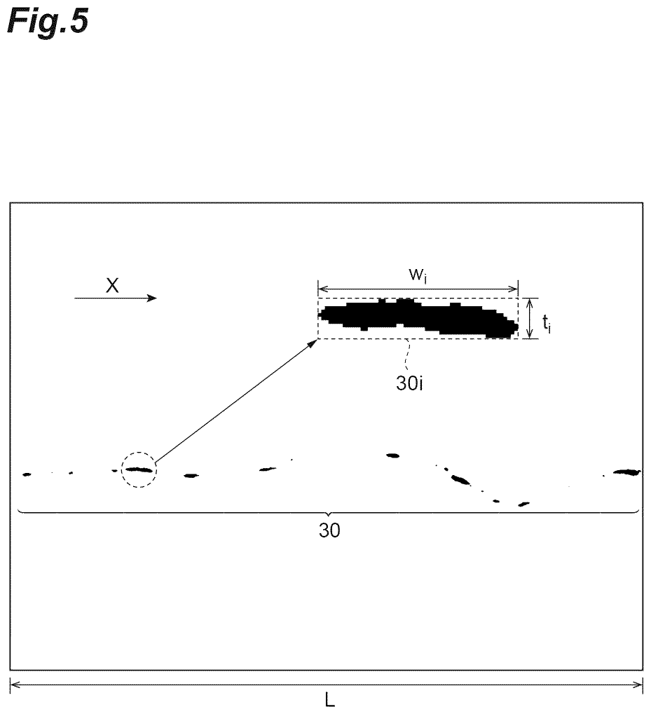

FIG. 3 is a cross-sectional view illustrating an example of a region observed for determining the BP occupancy in the cross section of the metal portion 25. FIG. 4 is an example of a scanning electron microscope image of the cross section of the metal portion. FIG. 5 is an image obtained by binarizing a portion of the metal portion in the scanning electron microscope image of FIG. 4. The scanning electron microscope image of FIG. 4 includes also a part of the insulating resin layer constituting the substrate located below the metal portion. In FIG. 5, an enlarged view of one black portion 30i is also illustrated. A method for determining the BP occupancy includes: determining a number n of black portions 30 observed by a scanning electron microscope in a region R having a width of L [μm] in a direction X parallel to the main surface 1S of the substrate 1 in the cross section of the metal portion 25; determining a maximum width wᵢ [μm] in a direction X of each of the n black portions 30; and calculating the BP occupancy according to the following equation:

$$BP occupancy ( \% ) = {\sum }_{i = 1}^{n} {w}_{i} \times \frac{1}{L} \times 100 .$$

The BP occupancy may be determined in two or more regions R, and an average value thereof may be determined. When n black portions are denoted by a number i, which is an integer from 1 to n, the maximum width wᵢ of each black portion 30i is a maximum width of the black portion 30i of number i. The maximum width wᵢ can be the width of the black portion of number i when the black portion is viewed from a direction (thickness direction of the substrate 1) perpendicular to the direction X. A maximum thickness ti of each black portion 30i in the thickness direction (direction perpendicular to the direction X) of the substrate 1 is usually 0.3 μm or less.

When the electrolytic plating layer 21 and the wiring 2 include a portion having a width W of less than 10 μm, the BP occupancy may be determined by observing the black portion in the region having a width of L [μm] in the direction parallel to the main surface 1S of the substrate 1 in the cross section of the metal portion 25 including the copper plating layer 21 having a width of less than 10 μm. The BP occupancy in the cross section including a portion of the copper plating layer 21 having a width of less than 10 μm may greatly affect the adhesion between the copper plating layer 21 and the seed layer 20. A large BP occupancy can lead to, for example, formation of a large hole from the black portion when an unnecessary portion of the seed layer is removed by an etching liquid, and, as a result, a fine wiring can collapse.

When the BP occupancy is 45% or less, adhesion between the copper plating layer 21 and the seed layer 20 can be particularly remarkably enhanced. From the same viewpoint, the BP occupancy may be 40% or less, or 35% or less. The BP occupancy may be 0% or more, 5% or more, 10% or more, 15% or more, 20% or more, or 25% or more. The BP occupancy of 0% means that the black portion is not substantially observed.

The copper plating layer 21 may be formed so that the BP occupancy falls within a predetermined range (for example, 45% or less). For example, the resist layer is selected so that the BP occupancy falls within a predetermined range, thereby making it possible to easily obtain a wiring board exhibiting high adhesion between the copper plating layer 21 and the seed layer 20. Furthermore, the resist layer can be evaluated based on the BP occupancy. For example, the quality of the resist layer can be judged based on whether the BP occupancy falls within a predetermined range (for example, 45% or less). An example of a configuration of the resist layer that easily gives a low BP occupancy will be described later.

The wiring board can also be evaluated based on the BP occupancy. In that case, for example, the quality of the wiring board can be judged based on whether the BP occupancy in the cross section of the wiring falls within a predetermined range (for example, 45% or less).

The resist layer 3 can be formed of a photosensitive resist material. A thickness of the resist layer 3 may be, for example, 5 μm or more and 120 μm or less, 5 μm or more and 50 μm or less, 10 μm or more and 120 μm or less, or 10 μm or less and 50 μm or less.

The resist layer 3 is formed by forming a film from a resist material. The resist material (or the resist layer 3 before exposure) may be, for example, a photosensitive resin composition containing a binder polymer, a photopolymerizable component containing a compound having an ethylenically unsaturated bond, and a photopolymerization initiator.

The binder polymer can be, for example, an acrylic polymer containing (meth)acrylic acid and a (meth)acrylic acid ester as monomer units. A proportion of the monomer unit derived from the (meth)acrylic acid in the acrylic polymer may be 5 to 30 mass %, 5 to 25 mass %, or 10 to 25 mass % based on a mass of the acrylic polymer.

The acrylic polymer may be a copolymer containing (meth)acrylic acid and a (meth)acrylic acid benzyl ester or a derivative thereof as monomer units, a copolymer containing (meth)acrylic acid and styrene or a styrene derivative as monomer units, or a copolymer containing (meth)acrylic acid, a (meth)acrylic acid benzyl ester or a derivative thereof, and styrene or a styrene derivative as monomer units. The acrylic polymer containing these monomer units may further contain a (meth)acrylic acid alkyl ester as a monomer unit.

Specific examples of the (meth)acrylic acid benzyl ester derivative constituting the acrylic polymer include 4-methylbenzyl (meth)acrylate, 4-ethylbenzyl (meth)acrylate, 4-tert-butylbenzyl (meth)acrylate, 4-methoxybenzyl (meth)acrylate, 4-ethoxybenzyl (meth)acrylate, 4-hydroxylbenzyl (meth)acrylate, and 4-chlorobenzyl (meth)acrylate. The acrylic polymer may contain two or more (meth)acrylic acid benzyl esters as monomer units, or may contain both of (meth)acrylic acid benzyl ester and a derivative thereof as monomer units.

A proportion of the monomer unit derived from the (meth)acrylic acid benzyl ester or derivative thereof in the acrylic polymer may be 50 to 80 mass %, 50 to 75 mass %, 50 to 70 mass %, or 50 to 65 mass % based on the mass of the acrylic polymer.

Specific examples of the styrene derivative constituting the acrylic polymer include vinyltoluene, p-methylstyrene, p-chlorostyrene, α-methylstyrene, p-hydroxystyrene, p-methoxystyrene, p-carboxystyrene, and p-(2-chloroethyl) styrene. The acrylic polymer may contain two or more styrene derivatives as monomer units, or may contain both styrene and a derivative thereof as monomer units.

A proportion of the monomer unit derived from the styrene or the styrene derivative in the acrylic polymer may be 5 to 40 mass % or 5 to 35 mass % based on the mass of the acrylic polymer.

The (meth)acrylic acid alkyl ester constituting the acrylic polymer may be an ester compound formed of (meth)acrylic acid and a linear or branched aliphatic alcohol having 1 to 12 carbon atoms. The aliphatic alcohol may have 1 to 8 or 1 to 4 carbon atoms. Specific examples of the (meth)acrylic acid alkyl ester include methyl (meth)acrylate, ethyl (meth)acrylate, propyl (meth)acrylate, isopropyl (meth)acrylate, butyl (meth)acrylate, tert-butyl (meth)acrylate, pentyl (meth)acrylate, hexyl (meth)acrylate, heptyl (meth)acrylate, octyl (meth)acrylate, and 2-ethylhexyl (meth)acrylate. The (meth)acrylic acid alkyl ester constituting the acrylic polymer may have a hydroxyl group. Specific examples of the (meth)acrylic acid alkyl ester having a hydroxyl group include 2-hydroxyethyl (meth)acrylate. The acrylic polymer may contain two or more (meth)acrylic acid alkyl esters as monomer units.

A proportion of the monomer unit derived from the (meth)acrylic acid alkyl ester in the acrylic polymer may be 1 to 20 mass %, 1 to 15 mass %, 1 to 10 mass %, or 1 to 5 mass % based on the mass of the acrylic polymer.

A weight average molecular weight (Mw) of the binder polymer (or acrylic polymer) may be 20000 to 150000, 30000 to 100000, 40000 to 80000, or 40000 to 60000. The weight average molecular weight as used herein means a value in terms of standard polystyrene as determined by gel permeation chromatography (GPC).

An acid value (mgKOH/g) of the binder polymer may be 13 to 78, 39 to 65, or 52 to 62. The acid value as used herein means an amount (mg) of potassium hydroxide required for neutralization of 1 g of the binder polymer.

A content of the binder polymer (or acrylic polymer) in the resist material (or the resist layer 3 before exposure) may be 40 to 80 parts by mass, 45 to 75 parts by mass, or 50 to 70 parts by mass with respect to 100 parts by mass of a total amount of the binder polymer and the photopolymerizable component.

Specific examples of the photopolymerizable component include a bisphenol A-based (meth)acrylate compound, a hydrogenated bisphenol A-based (meth)acrylate compound, a polyalkylene glycol (meth)acrylate, a urethane monomer, pentaerythritol (meth)acrylate, and trimethylolpropane (meth)acrylate. These may be used singly, or two or more thereof may be used in combination. The bisphenol A-based (meth)acrylate compound may be, for example, a compound represented by the following general formula (1A).

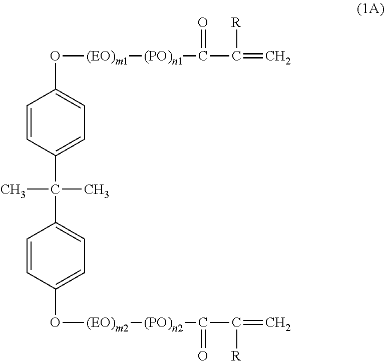

In Formula (1A), two Rs each independently represent a hydrogen atom or a methyl group. EO represents an oxyethylene group, and PO represents an oxypropylene group. m1, m2, n1, and n2 each independently represent 0 to 40, m1+m2 represents 1 to 40, and n1+n2 represents 0 to 20. A bonding order of EO and PO is not limited, and either may be located on a (meth)acryloyl group side.

The polyalkylene glycol (meth)acrylate may be a compound represented by the following formula (1B).

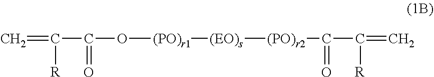

In Formula (1B), two Rs each independently represent a hydrogen atom or a methyl group, EO represents an oxyethylene group, PO represents an oxypropylene group, s represents 1 to 30, r1 and r2 each independently represent 0 to 30, and r1+r2 represents 1 to 30. Examples of commercially available products of the compound represented by

Formula (1B) include compounds (trade name: FA-023M, manufactured by Showa Denko Materials co., Ltd.) in which R is a methyl group, r¹+r²=4 (average value), and s=12 (average value).

The photopolymerizable component in the resist material (or the resist layer 3 before exposure) may contain a photopolymerizable compound having an oxyalkylene group. The resist material containing the photopolymerizable compound having an oxyalkylene group can contribute to a decrease in BP occupancy. For example, a content of the photopolymerizable compound having an oxyalkylene group may be 35 parts by mass or more, 40 parts by mass or more, 45 parts by mass or more, 50 parts by mass or more, or 55 parts by mass or more, and may be 65 parts by mass or less or 60 parts by mass or less, with respect to 100 parts by mass of a total amount of the binder polymer and the photopolymerizable compound. The photopolymerizable compound having an oxyalkylene group may be, for example, a bisphenol A-based di(meth)acrylate compound represented by Formula (1A), a polyalkylene glycol (meth)acrylate represented by Formula (1B), or a combination thereof.

Specific examples of the photopolymerization initiator include aromatic ketones such as benzophenone, N,N′-tetramethyl-4,4′-diaminobenzophenone (Michler's ketone), N,N′-tetraethyl-4,4′-diaminobenzophenone, 4-methoxy-4′-dimethylaminobenzophenone, 2-benzyl-2-dimethylamino-1-(4-morpholinophenyl)-butanone-1, and 2-methyl-1-[4-(methylthio)phenyl]-2-morpholino-propanone-1; quinones such as 2-ethylanthraquinone, phenanthrenequinone, 2-tert-butylanthraquinone, octamethylanthraquinone, 1,2-benzanthraquinone, 2,3-benzanthraquinone, 2-phenylanthraquinone, 2,3-diphenylanthraquinone, 1-chloroanthraquinone, 2-methylanthraquinone, 1,4-naphthoquinone, 9,10-phenanthraquinone, 2-methyl1,4-naphthoquinone, and 2,3-dimethylanthraquinone; benzoin ether compounds such as benzoin methyl ether, benzoin ethyl ether, and benzoin phenyl ether, and benzoin compounds such as benzoin, methylbenzoin, and ethylbenzoin; at least one 2,4,5-triarylimidazole dimer derivative selected from benzyl derivatives such as benzyldimethylketal, 2-(o-chlorophenyl)-4,5-diphenylimidazole dimer, 2-(o-chlorophenyl)-4,5-di(methoxyphenyl) imidazole dimer, 2-(o-fluorophenyl)-4,5-diphenylimidazole dimer, 2-(o-methoxyphenyl)-4,5-diphenylimidazole dimer, and 2-(p-methoxyphenyl)-4,5-diphenylimidazole dimer; acridine derivatives such as 9-phenylacridine and 1,7-bis(9,9′-acridinyl) heptane; N-phenylglycine; N-phenylglycine derivatives; and coumarin-based compounds. These may be used singly, or two or more thereof may be used in combination. The photopolymerization initiator may contain a 2,4,5-triarylimidazole dimer derivative, particularly a 2-(O-chlorophenyl)-4,5-diphenylimidazole dimer. Formulation of the 2,4,5-triarylimidazole dimer derivative may contribute to a reduction in BP occupancy.

The 2,4,5-triarylimidazole dimer derivative is represented by, for example, the following formula (2).

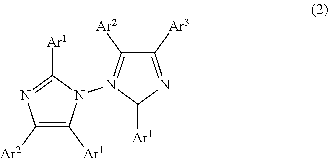

In Formula (2), Ar¹, Ar² and Ar³ each independently represent an aryl group (for example, a phenyl group) which may have a substituent. Examples of the substituent which the aryl group as Ar¹, Ar² or Ar³ may have include a halogeno group (for example, a chloro group or a fluoro group) and an alkoxy group (for example, a methoxy group). Ar¹ may be an aryl group having a substituent.

A content of the photopolymerization initiator in the resist material (or the resist layer 3 before exposure) may be 0.01 to 5 parts by mass, 0.1 to 4.5 parts by mass, or 1 to 4 parts by mass with respect to 100 parts by mass of the total amount of the binder polymer and the photopolymerizable component. A content of the 2,4,5-triarylimidazole dimer derivative in the resist material (or the resist layer 3 before exposure) may be 5 parts by mass or more, 6 parts by mass or more, 7 parts by mass or more, or 8 parts by mass or more, and may be 12 parts by mass or less, 11 parts by mass or less, 10 parts by mass or less, 9 parts by mass or less, 8.5 parts by mass or less, or 8 parts by mass or less, with respect to 100 parts by mass of the total amount of the binder polymer and the photopolymerizable component. A content of the photopolymerization initiator (particularly, 2,4,5-triarylimidazole dimer derivative) falling within an appropriate range can contribute to improvement of a shape of the pattern formed by the resist layer 3 in addition to improvement of the sensitivity, resolution, and adhesion of the resist material.

The resist material (or the resist layer 3 before exposure) may contain a dye. The dye may be, for example, at least one selected from the group consisting of Leuco dye, Phthalocyanine Green, Crystal Violet, Methyl Orange, Nile Blue 2B, Victoria Blue, Malachite Green, Basic Blue 20, and Diamond Green. The Leuco dye may be, for example, Leuco Crystal Violet, a fluoran dye, or a combination thereof. The Leuco Crystal Violet may also function as a hydrogen donor.

A content of the dye may be 0.01 to 20 parts by mass with respect to 100 parts by mass of the total amount of the binder polymer and the photopolymerizable component. A content of the Leuco dye may be 0.1 parts by mass or more and 0.5 parts by mass or less, 0.1 parts by mass or more and 0.4 parts by mass or less, or 0.1 parts by mass or more and 0.3 parts by mass or less with respect to 100 parts by mass of the total amount of the binder polymer and the photopolymerizable component. A content of the Malachite Green may be 0.05 parts by mass or less, 0.04 parts by mass or less, 0.03 parts by mass or less, or 0.02 parts by mass or less, and may be 0 parts by mass or more, with respect to 100 parts by mass of the total amount of the binder polymer and the photopolymerizable component. The contents of the Leuco dye and the Malachite Green can affect the BP occupancy.

The resist material (or the resist layer 3 before exposure) may contain other components as necessary. Examples of such other components include a sensitizer, a polymerization inhibitor, and an adhesive component. A content of each of such other components may be 0.01 to 20 parts by mass with respect to 100 parts by mass of the total amount of the binder polymer and the photopolymerizable component. The adhesive component may include, for example, 5-amino-1H-tetrazole. A content of the adhesive component can affect the BP occupancy.

A total content of the binder polymer, the photopolymerizable component, and the photopolymerization initiator in the resist material (or the resist layer 3 before exposure) may be 90 to 100 mass % or 95 to 100 mass % with respect to a total mass of components other than the solvent in the resist material (resist layer 3).

In order to form the resist layer 3, a resist film containing a resist material may be laminated on the seed layer 20, or a resist material containing a solvent may be applied to the seed layer 20, and the solvent may be removed from the coating film.

A part of the resist layer 3 is exposed, and the exposed resist layer 3 is developed to form the resist layer 3 having a pattern including the opening 3A. Exposure and development can be performed by a common method known to those skilled in the art. By exposure via a photomask, a fine pattern including the opening 3A through which the seed layer 20 is exposed is formed. A developer for development may be an aqueous alkali solution such as an aqueous sodium carbonate solution. Conditions for development may be selected so that the BP occupancy is 45% or less. For example, a long development time (contact time between the resist layer and the developer) results in a tendency of decreasing the BP occupancy. A temperature of the developer may be, for example, 20 to 40° C.

After the pattern of the resist layer 3 including the opening 3A is formed, the surface 20S of the seed layer 20 exposed in the opening 3A may be pretreated by contact with a pretreatment liquid at a predetermined pretreatment temperature before electrolytic plating. By immersing an intermediate structure including the substrate 1, the seed layer 20, and the resist layer 3 having a pattern in a pretreatment liquid adjusted to a predetermined pretreatment temperature, the surface of the seed layer 20 can be pretreated. Conditions for pretreatment may be selected so that the BP occupancy is 45% or less. For example, a temperature of the pretreatment liquid may be in a range of 20 to 50° C. An immersion time in the pretreatment liquid may be, for example, 1 minute or more or 2 minutes or more, and may be 8 minutes or less.

The pretreatment liquid may be, for example, an acidic aqueous solution containing an acid component, an additive for electrolytic plating, and a reducing agent.

The acid component may be an organic acid, an inorganic acid, or a combination thereof, and specific examples thereof include sulfuric acid; alkanesulfonic acids such as methanesulfonic acid and propanesulfonic acid; alkanolsulfonic acids such as isethionic acid and propanolsulfonic acid; carboxylic acids such as citric acid, tartaric acid, and formic acid. These may be used singly, or two or more thereof may be used in combination. A concentration of the acid component in the pretreatment liquid may be 10 to 300 g/L or 50 to 200 g/L based on a volume of the pretreatment liquid.

The additive for electrolytic plating may be, for example, a polyether compound, an organosulfur compound, or a combination thereof. Examples of the polyether compound include polyethylene glycol, polypropylene glycol, and derivatives thereof. The organosulfur compound is a copper plating deposition accelerator sometimes referred to as brightener, examples thereof include 3-mercaptopropane sulfonic acid and bis(3-sulfopropyl) disulfide disodium salt. A concentration of the additive in the pretreatment liquid may be 0.1 to 10000 mg/L based on the volume of the pretreatment liquid.

Examples of the reducing agent include hypophosphite, phosphite, dimethylamine borane, trimethylamine borane, hydrazine derivatives, borohydride salts, aldehyde compounds (e.g. formalin and glyoxylic acid), titanium trichloride, catechol, resorcin, hydroquinone, ascorbate, phenylenediamine, and phosphinic acid derivatives. These may be used singly, or two or more thereof may be used in combination. A concentration of the reducing agent in the pretreatment liquid may be 0.0001 to 0.1 mol/L based on the volume of the pretreatment liquid.

The pretreatment liquid may further contain a surfactant selected from an alkylbenzene sulfonate, a compound having an acetylene group, and the like. The pretreatment liquid may contain a carboxylic acid or an alkanesulfonic acid, an inorganic acid selected from hydrochloric acid, sulfuric acid, phosphoric acid, and nitric acid, an alkylbenzene sulfonate, and a compound having an acetylene group. In this case, a content of the carboxylic acid and the alkanesulfonic acid may be 5 to 50 g/L or 10 to 20 g/L based on the volume of the pretreatment liquid, and a content of the inorganic acid may be 1 to 20 g/L or 2 to 10 g/L based on the volume of the pretreatment liquid.

The alkylbenzene sulfonate is a salt of a sulfonic acid compound having a benzene ring and an alkyl group and a sulfonic acid group bonded to the benzene ring. The alkyl group may have 10 to 16 carbon atoms. The alkylbenzene sulfonate may be a sodium salt, a potassium salt, or a triethanolamine salt. Specific examples of the alkylbenzene sulfonate include sodium linear dodecylbenzene sulfonate. A content of the alkylbenzene sulfonate may be 0.5 to 20 g/L based on the volume of the pretreatment liquid.

Examples of commercially available products of the surfactant which is the compound having an acetylene group include Surfynol 104, Surfynol 440, and Surfynol 465 (trade name: manufactured by Nissin Chemical Co., Ltd.). A content of the compound having an acetylene group may be 0.1 to 5 g/L or 0.3 to 1 g/L based on the volume of the pretreatment liquid.

The pretreatment liquid may contain a dispersant. The dispersant may be a polymer containing a monomer unit derived from maleic acid, and examples of commercially available products thereof include MALIALIAM AKM-0531 (trade name: manufactured by NOF CORPORATION). A content of the dispersant may be 0.1 to 5 g/L or 0.3 to 1 g/L based on the volume of the pretreatment liquid.

Before the electrolytic plating, the surface 20S of the seed layer 20 exposed in the opening 3A may be treated with plasma. Plasma treatment may also contribute to a reduction in BP occupancy.

On the surface of the pretreated seed layer 20, the copper plating layer 21 for filling the opening 3A is formed by electrolytic plating. Thereafter, the resist layer 3 is peeled off from the seed layer 20. The seed layer 20 at a portion exposed by peeling of the resist layer 3 is removed by a normal method such as etching. As a result, the wiring 2 composed of the seed layer 20 remaining on the substrate 1 and the metal plating layer 21 is formed.

The electrolytic plating layer 21 and the wiring 2 may include a linear portion, and a width W of the linear portion may be, for example, 20 μm or less, 15 μm or less, 10 μm or less, less than 10 μm, 9 μm or less, 8 μm or less, 7 μm or less, 6 μm or less, 5 μm or less, less than 5 μm, or 4.9 μm or less, and may be 1 μm or more, 2 μm or more, 3 μm or more, 4 μm or more, or 5 μm or more. The width W as used herein means a width in a direction perpendicular to a longitudinal direction of the linear portion. When the width W is small, the adhesion between the copper plating layer 21 and the seed layer 20 tends to be more strongly correlated with the BP occupancy, for example, as compared with the number of black portions. The reason is considered to be that, for example, when a small width W of the copper plating layer 21 results in a tendency of increasing the size of the individual black portions.

### EXAMPLES

The present invention is not limited to the following Examples.

### 1. Resist Film

Resist films 1 and 2 containing the components shown in Table 1 and including a 19 μm-thick resist layer and protective films provided on both sides of the resist layer were prepared. In the table, the content (parts by mass) of each component with respect to 100 parts by mass of the total amount of the binder polymer and the photopolymerizable component is shown.

TABLE 1

| Resist film | | 1 | 2 |
|---|---|---|---|
| Binder polymer | Acrylic polymer 1 | — | 60 |
| | Acrylic polymer 2 | 60 | — |
| Photopolymerizable | Monomer A | 40 | 40 |
| component | Monomer B | | |
| | Monomer C | | |
| Photopolymerization initiator | B-CIM | 6 | 4 |
| Sensitizer | DBA | 0.5 | — |
| | EAB | — | 0.4 |
| Dye | LCV | 1 | 1 |
| | MKG | 0.1 | 0.1 |

Details of each component shown in the table are as follows.

### (A) Binder Polymer

Acrylic polymer 1: copolymer of methacrylic acid, styrene, methacrylic acid benzyl ester, methacrylic acid, and methyl methacrylate
Acrylic polymer 2: copolymer of methacrylic acid, styrene, methacrylic acid benzyl ester, and 2-hydroxyethyl methacrylate

### (B) Photopolymerizable Component

Monomer A: polyoxyethylenated bisphenol A dimethacrylate (compound represented by Formula (1A))
Monomer B: polyoxyalkylene glycol dimethacrylate (compound represented by Formula (1B))
Monomer C: polyoxyethylenated bisphenol A dimethacrylate (compound represented by Formula (1A))

### (C) Photopolymerization Initiator

B-CIM: 2,2′-bis(o-chlorophenyl)-4,5-4′,5′-tetraphenyl-1,2′-biimidazole

### (D) Sensitizer

DBA: 9,10-dibutoxyanthracene
EAB: 4,4′-bis(diethylamino)benzophenone

### (E) Dye

LCV: Leuco Crystal Violet
MKG: Malachite Green

### 2. Preparation of Wiring Board

### Pattern Formation of Resist Layer

A substrate including a support substrate as a laminate of prepregs and an insulating resin layer provided on the support substrate was prepared. A seed layer (electroless copper plating layer, thickness: about 0.5 μm) was formed on the insulating resin layer. The resist film 1 or 2 from which one protective film had been removed was laminated on the seed layer in such an orientation in which the resist layer was in contact with the seed layer. Subsequently, the resist layer on the seed layer was exposed via a negative photomask. After the exposure, the protective film was peeled off, and a pattern including a linear opening having a width of 7 μm was formed in the resist layer by development using a 1.0% aqueous sodium carbonate solution as a developer. The seed layer was exposed in the opening. The development was performed by spraying with a developer for a time of 1.5 MD, 1.7 MD, or 2 MD (development time) and subsequent spraying with pure water for 100 seconds, using an ultra-high pressure spin developing device (manufactured by Blue Ocean Technology., Ltd.) including a spray nozzle. The development temperature was 30° C., the rotation speed was 500 rpm, the spray pressure was 0.18 MPa, the moving distance of the spray nozzle head was 7.2 cm, and the moving speed of the spray nozzle head was 10 cm/s. The “MD” for the development time means a proportion to the minimum development time required to remove the resist layer at which no pattern is formed.

### Pretreatment

A laminate composed of an insulating substrate, the seed layer, and the resist layer having an opening was immersed in an acidic pretreatment liquid (100 mL/L aqueous solution of PB-242D manufactured by JCU CORPORATION, 45° C.) for 1 minute or 3 minutes for pretreatment. Thereafter, the laminate was immersed in pure water at 50° C. for 1 minute, pure water at 25° C. for 1 minute, and a 10% aqueous sulfuric acid solution at 25° C. for 1 minute in this order.

### Electrolytic Plating

The pretreated laminate was immersed in an electrolytic plating liquid, and a copper plating layer was formed on the seed layer over 10 minutes under the condition of a current density of 10 A/dm² at 25° C. As the electrolytic plating liquid, a mixed solution of 7.3 L of an aqueous solution containing 120 g/L of copper sulfate pentahydrate and 220 g/L of 96% sulfuric acid, 0.25 mL of hydrochloric acid, 92 mL of TOP LUCINA NSV-1 (trade name, manufactured by Okuno Chemical Industries Co., Ltd.), 11.5 mL of TOP LUCINA NSV-2 (trade name, manufactured by Okuno Chemical Industries Co., Ltd.), and 23 mL of TOP LUCINA NSV-3 (trade name, manufactured by Okuno Chemical Industries Co., Ltd.) was used. After formation of the copper plating layer, the laminate was immersed in pure water at room temperature for 1 minute, and the immersed laminate was dried. The resist layer was peeled off by immersion in a peeling liquid (Clean Etch R100/R100S (manufactured by MITSUBISHI GAS CHEMICAL COMPANY, INC.) at 60° C. for 3 minutes to obtain laminates #1 to #7 for evaluation each including a metal portion including the seed layer and the copper plating layer. Preparation conditions for each laminate are shown in Table 2.

### 3. Evaluation

### 3-1. Black Portion

The laminate for evaluation was processed using a focused ion beam apparatus (MI4050, manufactured by Hitachi High-Tech Corporation) to prepare a test piece in which the vicinity of the interface between the seed layer and the copper plating layer was exposed and which had a cross section substantially parallel to the thickness direction of the laminate for evaluation. The cross section of the test piece was observed using a scanning electron microscope (SU8200, manufactured by Hitachi High-Tech Corporation) from a direction of 30° with respect to the thickness direction of the test piece in a plane parallel to the thickness direction of the test piece and perpendicular to the cross section of the test piece, and photographed at a magnification of 50000 times. In the metal portion in the obtained cross-sectional photograph, a region having a width L of 7 μm in a direction parallel to the main surface of the substrate was binarized so that only a minute black portion observed in the vicinity of the interface between the seed layer and the copper plating layer became black. Image editing software ImageJ was used for binarization.

In the binarized image, the number n of black portions, the area Si (i=1 to n) of the individual black portions, and the maximum width wᵢ of the individual black portions in the direction parallel to the main surface of the substrate were determined. From the obtained values, the number of black portions per 1 μm of the width of the copper plating layer (BP number density, count/μm), the average area Sₘ (μm²) of the black portions, the total area Sₜₒₜₐₗ (μm²/μm) of the black portions per 1 μm of the width of the copper plating layer, and the BP occupancy were calculated by the following equations. The results are shown in Table 2.

$$BP occupancy density = n \times \frac{1}{L}$$

$${S}_{m} = {\sum }_{i = 1}^{n} {S}_{i} \times \frac{1}{n} \times \frac{1}{sin 30 °}$$

$${S}_{t o t a l} = {\sum }_{i = 1}^{n} {S}_{i} \times \frac{1}{L} \times \frac{1}{sin 30 °}$$

$$BP occupancy ( \% ) = {\sum }_{i = 1}^{n} {w}_{i} \times \frac{1}{L} \times 100$$

TABLE 2

| Laminate | #1 | #2 | #3 | #4 | #5 | #6 | #7 |
|---|---|---|---|---|---|---|---|
| Resist film | 2 | 1 | 1 | 2 | 1 | 2 | 1 |
| Copper | 7 | 7 | 7 | 7 | 7 | 7 | 7 |
| plating layer | | | | | | | |
| width, μm | | | | | | | |
| Development | 2 | 2 | 1.7 | 1.5 | 1.5 | 1.5 | 1.5 |
| time, MD | | | | | | | |
| Immersion | 3 | 3 | 3 | 3 | 3 | 1 | 1 |
| time in acidic | | | | | | | |
| pretreatment | | | | | | | |
| liquid, min | | | | | | | |
| BP number | 6.3 | 6.8 | 6.7 | 9.4 | 5.7 | 9.1 | 11.9 |
| density, | | | | | | | |
| count/μm² | | | | | | | |
| Sm/μm² | 1.4 × 10⁻³ | 1.4 × 10⁻³ | 2.0 × 10⁻³ | 1.3 × 10⁻³ | 2.6 × 10⁻³ | 1.9 × 10⁻³ | 1.7 × 10⁻³ |
| Sₜₒₜₐₗ/μm² | 8.3 × 10⁻³ | 9.5 × 10⁻³ | 13.0 × 10⁻³ | 11.6 × 10⁻³ | 14.8 × 10⁻³ | 16.9 × 10⁻³ | 18.9 × 10⁻³ |
| BP | 30.2 | 32.5 | 45.0 | 53.3 | 60.8 | 63.7 | 65.5 |
| occupancy, | | | | | | | |
| % | | | | | | | |

### 3-2. Peel Strength

The peel strength (N/mm) between the copper plating layer having a width of 7 μm and the seed layer was measured by a peel test in which the copper plating layer was cut and peeled off with a minute diamond cutting edge using SAICAS N-05 type (trade name, DAIPLA WINTES CO., LTD.). Measurement conditions were as follows. Two measurements were performed, and an average value of the obtained peel strengths was determined.
Measurement mode: constant speed mode
Horizontal speed: 1000 nm/sec
Perpendicular speed: 100 nm/sec
Rake angle: 20°, clearance angle: 10°

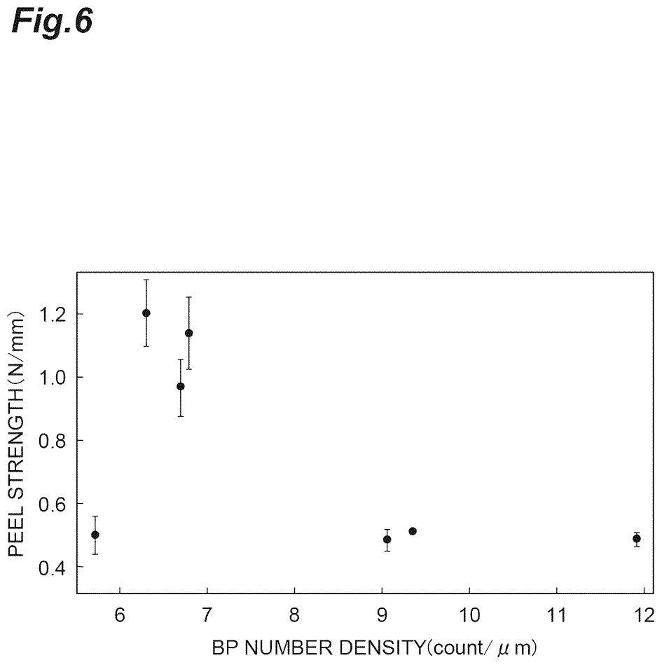

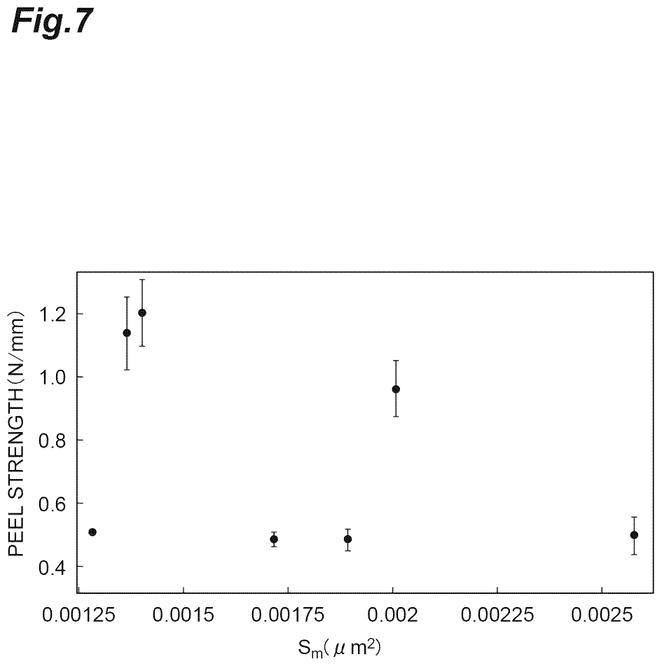

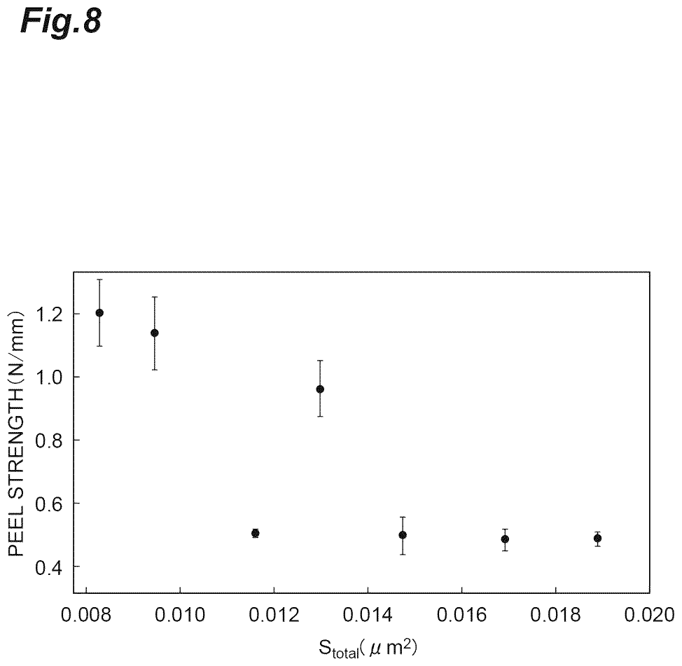

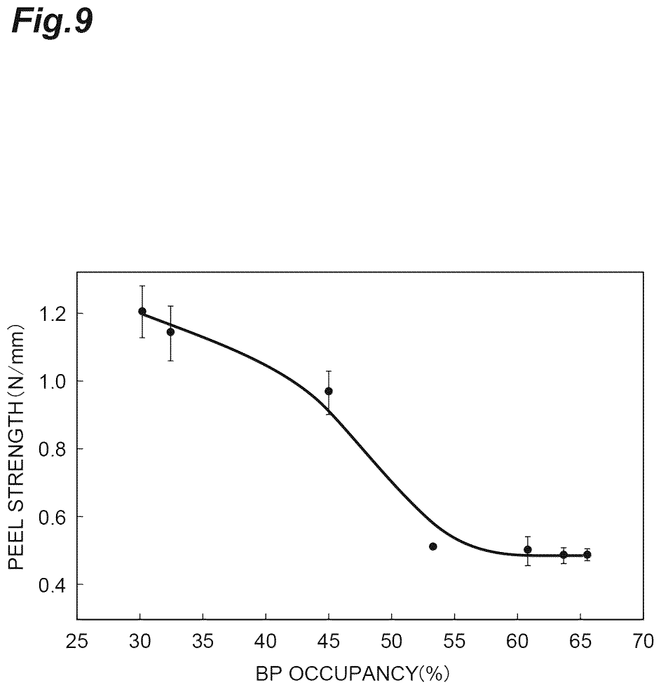

FIGS. 6, 7, 8, and 9 are graphs illustrating the relationship between the peel strength and the BP number density, Sₘ, Sₜₒₜₐₗ, and the BP occupancy, respectively. The BP occupancy showed the best correlation with peel strength. In particular, it was confirmed that, when the BP occupancy rate was 45% or less, the peel strength remarkably increased.

### REFERENCE SIGNS LIST

1 Substrate
2 Wiring
3 Resist layer
10 Wiring board
20 Seed layer
20S Surface of seed layer opposite to substrate
21 Copper plating layer
25 Metal portion
30 Black portion
wi Maximum width of black portion
W Copper plating layer and wiring width

1. A method for manufacturing a wiring board, the method comprising:
providing a resist layer on a seed layer comprising a metal, the seed layer being provided on a main surface of a substrate;
forming a pattern including an opening through which the seed layer is exposed at the resist layer by exposure and development of the resist layer; and
forming a copper plating layer comprising a portion having a width of less than 10 μm on the seed layer exposed in the opening by electrolytic plating, wherein
the copper plating layer is formed so that a BP occupancy that is an occupancy of a black portion observed in a cross section of a metal portion comprising the seed layer and the copper plating layer in a width direction of the copper plating layer, is 45% or less, and
the BP occupancy is a value as determined by a method comprising:
determining a number n of black portions observed in a region having a width of L [μm] in a direction parallel to the main surface of the substrate in a cross section of the metal portion comprising the copper plating layer having a width of less than 10 μm;
determining a maximum width wᵢ [μm] of each of the n black portions in a direction parallel to the main surface of the substrate; and
calculating the BP occupancy according to a following equation:
$$BP occupancy ( \% ) = {\sum }_{i = 1}^{n} {w}_{i} \times \frac{1}{L} \times 100 .$$

2. The method according to claim 1, further comprising:
removing the resist layer to expose a portion of the seed layer that is not covered with the copper plating layer; and
removing an exposed portion of the seed layer with an etching liquid to form a wiring board comprising: a wiring comprising the seed layer and the copper plating layer; and the substrate.

3. The method according to claim 1, wherein
the resist layer comprises a binder polymer, a photopolymerizable component, and a photopolymerization initiator, and the resist layer is selected so that the BP occupancy is 45% or less.

4. The method according to claim 3, wherein the photopolymerization initiator comprises a 2,4,5-triarylimidazole dimer derivative.

5. The method according to claim 4, wherein a content of the 2,4,5-triarylimidazole dimer derivative in the resist layer is selected in a range of 6 parts by mass or more and 12 parts by mass or less with respect to 100 parts by mass of a total amount of the binder polymer and the photopolymerizable component.

6. The method according to claim 3, wherein the photopolymerizable component comprises a photopolymerizable compound having an oxyalkylene group.

7. (canceled)

8. A method for evaluating a wiring board comprising: a substrate; and a wiring provided on the substrate, wherein
the wiring comprises: a seed layer provided on the substrate; and a copper plating layer comprising a portion having a width of less than 10 μm, the copper plating layer being formed on the seed layer,
the method comprises determining a BP occupancy that is an occupancy of a black portion observed in a cross section of the wiring in a width direction of the copper plating layer, and
a method for determining the BP occupancy comprises:
determining a number n of black portions observed in a region having a width of L [μm] in a direction parallel to a main surface of the substrate in a cross section of the wiring comprising the copper plating layer having a width of less than 10 μm;
determining a maximum width wᵢ [μm] of each of the n black portions in a direction parallel to the main surface of the substrate; and
calculating the BP occupancy according to a following equation:
$$BP occupancy ( \% ) = {\sum }_{i = 1}^{n} {w}_{i} \times \frac{1}{L} \times 100 .$$

9. A wiring board comprising:
a substrate; and
a wiring provided on the substrate, wherein
the wiring comprises: a seed layer provided on the substrate; and a copper plating layer comprising a portion having a width of less than 10 μm, the copper plating layer being formed on the seed layer,
a BP occupancy that is an occupancy of a black portion observed in a cross section of the wiring in a width direction of the copper plating layer, is 45% or less, and
the BP occupancy is a value as determined by a method comprising:
determining a number n of black portions observed in a region having a width of L [μm] in a direction parallel to a main surface of the substrate in a cross section of the wiring comprising the copper plating layer having a width of less than 10 μm;
determining a maximum width wᵢ [μm] of each of the n black portions in a direction parallel to the main surface of the substrate; and
calculating the BP occupancy according to a following equation:
$$BP occupancy ( \% ) = {\sum }_{i = 1}^{n} {w}_{i} \times \frac{1}{L} \times 100 .$$
